(19) United States
(12) Patent Application Publication
(10) Pub. No.: US 2015/0270175 A1
(43) Pub. Date: Sep. 24, 2015

(54) PARTIALLY CRYSTALLIZED FIN HARD MASK FOR FIN FIELD-EFFECT-TRANSISTOR (FINFET) DEVICE

(71) Applicant: GLOBALFOUNDRIES Inc., Grand Cayman (KY)

(72) Inventors: Xiang Hu, Clifton Park, NY (US); Andy Chih-Hung Wei, Queensbury, NY (US); Dae-han Choi, Loudonville, NY (US); Mariappan Hariharaputhiran, Ballston Lake, NY (US); Weihua Tong, Mechanicville, NY (US); Dae Geun Yang, Watervliet, NY (US); Akshey Sehgal, Malta, NY (US); Jing Wan, Malta, NY (US)

(73) Assignee: GLOBALFOUNDRIES Inc., Grand Cayman (KY)

(21) Appl. No.: 14/219,059

(22) Filed: Mar. 19, 2014

(51) Int. Cl. H01L 21/8234; H01L 21/027; H01L 21/306; H01L 21/324; H01L 29/78; H01L 21/308

(52) U.S. Cl. CPC H01L 21/823431; H01L 29/7851; H01L 21/3081; H01L 21/3086; H01L 21/30604; H01L 21/324; H01L 21/0276

(57) ABSTRACT

Provided herein are approaches for forming a fin field-effect-transistor (FinFET) device using a partially crystallized fin hard mask. Specifically, a hard mask is patterned over a substrate, and the FinFET device is annealed to form a set of crystallized hard mask elements adjacent a set of non-crystallized hard mask elements. A masking structure is provided over a first section of the patterned hard mask to prevent the set of non-crystallized hard mask elements from being crystallized during the anneal. During a subsequent fin cut process, the non-crystallized mask elements are removed, while crystallized mask elements remain. A set of fins is then formed in the FinFET device according to the location(s) of the crystallized mask elements.

### BACKGROUND

1. Technical Field

This invention relates generally to the field of semiconductors, and more particularly, to approaches for providing a partially crystallized fin hard mask for use in forming fins of a fin field-effect-transistor (FinFET) device.

2. Related Art

A typical integrated circuit (IC) chip includes a stack of several levels or sequentially formed layers of shapes. Each layer is stacked or overlaid on a prior layer and patterned to form the shapes that define devices (e.g., field effect transistors (FETs)) and connect the devices into circuits. In a typical state of the art complementary insulated gate FET process, such as what is normally referred to as CMOS, layers are formed on a wafer to form the devices on a surface of the wafer. Further, the surface may be the surface of a silicon layer on a silicon on insulator (SOI) wafer. A simple FET is formed by the intersection of two shapes, a gate layer rectangle on a silicon island formed from the silicon surface layer. Each of these layers of shapes, also known as mask levels or layers, may be created or printed optically through well known photolithographic masking, developing and level definition, e.g., etching, implanting, deposition, etc.

The FinFET is a transistor design that attempts to overcome the issues of short-channel effect encountered by deep submicron transistors, such as drain-induced barrier lowering (DIBL). Such effects make it harder for the voltage on a gate electrode to deplete the channel underneath and stop the flow of carriers through the channel—in other words, to turn the transistor off. By raising the channel above the surface of the wafer instead of creating the channel just below the surface, it is possible to wrap the gate around all but one of its sides, providing much greater electrostatic control over the carriers within it.

During the fabrication process of fin devices such as FinFETs, it is often desirable to provide isolation areas between fins. In one approach, the isolation area is opened using an organic planarization layer (OPL), a silicon anti-reflective coating (SiArc) layer located over the OPL, and a photoresist layer located on top of the OPL. However, during a hard mask cut process, erosion occurs at a top corner of Si-Arc layer during the OPL etch resulting in a tapered Si-Arc profile and curved OPL profile. The curved OPL profile is problematic because it causes either incomplete removal of the hard mask in the opened area of the OPL, or it causes unintended partial removal of hard mask sections that are covered by the OPL and intended to remain.

### SUMMARY

In general, embodiments herein provide approaches for forming a fin field-effect-transistor (FinFET) device using a partially crystallized fin hard mask. Specifically, a hard mask is patterned over a substrate, and the FinFET device is annealed to form a set of crystallized hard mask elements adjacent a set of non-crystallized hard mask elements. A masking structure is provided over a first section of the patterned hard mask to prevent the set of non-crystallized hard mask elements from being crystallized during the anneal. During a subsequent fin cut process, the non-crystallized mask elements are removed, while crystallized mask elements remain. A set of fins is then formed in the FinFET device according to the location(s) of the crystallized mask elements.

One aspect of the present invention includes a semiconductor device comprising: a substrate; and a hard mask patterned over the substrate, the hard mask comprising a set of crystallized hard mask elements adjacent a set of non-crystallized hard mask elements.

Another aspect of the present invention includes a method for forming a fin field-effect-transistor (FinFET) device, the method comprising: patterning a hard mask over a substrate; forming a set of crystallized hard mask elements adjacent a set of non-crystallized hard mask elements of the hard mask.

Another aspect of the present invention includes a method for forming a fin field-effect-transistor (FinFET) device using a partially crystallized fin hard mask, the method comprising: patterning a hard mask over a substrate; and annealing the hard mask to form a set of crystallized hard mask elements adjacent a set of non-crystallized hard mask elements.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a cross-sectional view of a semiconductor device following deposition of an amorphous carbon layer, an antireflective coating, and a photoresist over a patterned hard mask according to illustrative embodiments;

FIG. 2 shows a cross-sectional view of the semiconductor device following an etch to the antireflective coating according to illustrative embodiments;

FIG. 3 shows a cross-sectional view of the semiconductor device following an etch to the amorphous carbon layer to form a masking structure according to illustrative embodiments;

FIG. 4 shows a cross-sectional view of the semiconductor device following removal of the antireflective coating from atop the masking structure according to illustrative embodiments;

FIG. 5 shows a cross-sectional view of the semiconductor device following an anneal according to illustrative embodiments;

FIG. 6 shows a cross-sectional view of the semiconductor device following removal of the masking structure according to illustrative embodiments;

FIG. 7 shows a cross-sectional view of the semiconductor device following removal of a set of non-crystallized hard mask elements according to illustrative embodiments;

FIG. 8 shows a cross-sectional view of the semiconductor device following an etch to a second hard mask layer and an undoped oxide according to illustrative embodiments; and

FIG. 9 shows a cross-sectional view of the semiconductor device following formation of a set of fins according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which one or more approaches are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation, etc.

As stated above, embodiments herein provide approaches for forming a fin field-effect-transistor (FinFET) device using a partially crystallized fin hard mask. Specifically, a hard mask is patterned over a substrate, and the FinFET device is annealed to form a set of crystallized hard mask elements adjacent a set of non-crystallized hard mask elements. A masking structure is provided over a first section of the patterned hard mask to prevent the set of non-crystallized hard mask elements from being crystallized during the anneal. During a subsequent fin cut process, the non-crystallized mask elements are removed, while crystallized mask elements remain. A set of fins is then formed in the FinFET device according to the location(s) of the crystallized mask elements.

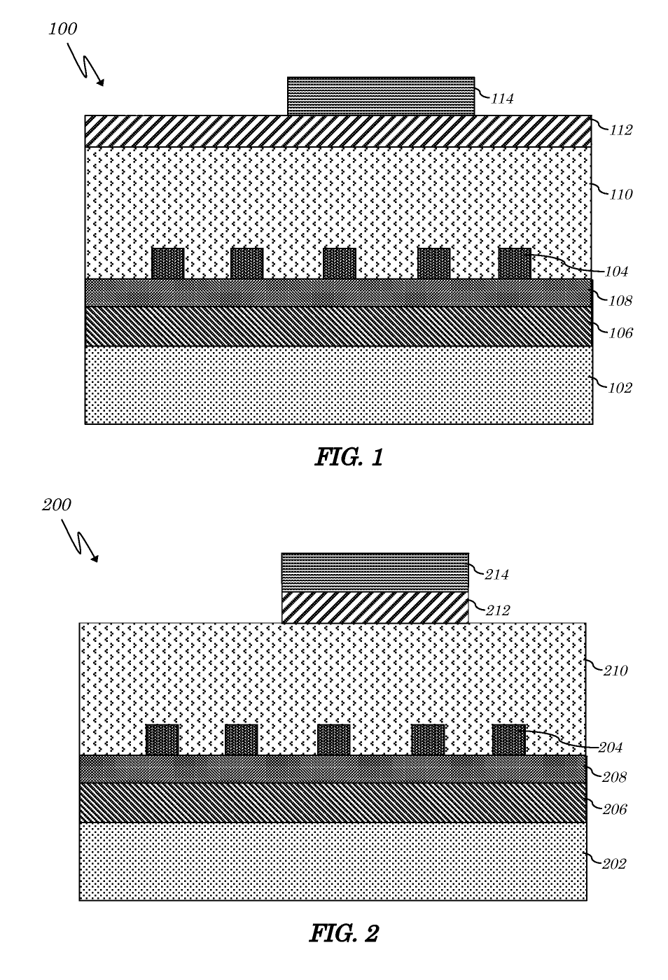

With reference now to the figures, FIG. 1 shows a semiconductor device 100 (e.g., a FinFET device) having a substrate 102 and a patterned hard mask 104 formed over substrate 102. Device 100 further comprises a second hard mask 106 formed atop substrate 102, and an undoped oxide (UDO) 108 formed over second hard mask 106. As will be described in further detail herein, hard mask 104 is partially crystallized during processing to assist in the subsequent formation of a set of fins in semiconductor device 100.

The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type semiconductor layers formed thereover or associated therewith. A portion or the entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped or contain doped regions and undoped regions therein. The semiconductor substrate may contain regions with strain and regions without strain therein, or contain regions of tensile strain and compressive strain.

In one embodiment, patterned hard mask 104 initially comprises a uniformly deposited material, e.g., a high dielectric constant (high-k) material. High-k materials may include, but are not limited to: hafnium silicate (HfSiO), hafnium oxide (HfO2), zirconium silicate (ZrSiOx), zirconium oxide (ZrO2), silicon oxide (SiO2), silicon nitride (Si3N4), silicon oxynitride (SiON), or any other high-k material (>4.0) or any combination of these materials. Selected portions of hard mask 104 are then removed using any suitable approach, including one or more photolithography and etch processes (not shown). The photolithography process may include forming a photoresist layer, exposing the resist to a pattern, performing post-exposure bake processes, and developing the resist to form a masking element including the resist.

In one embodiment, second hard mask 106 may comprise nitride (N), silicon nitride (SiN), silicon dioxide (SiO2), or any other material(s) suitable as a hard mask, including silicon oxynitride (SiON), silicon oxycarbide (SiOC), and the like. Second hard mask 106 can be prepared by PVD, CVD, spin coating, etc., depending on the material. It will be appreciated that second hard mask 106 may comprise multiple stacked layers, and is not limited to the uniform layer shown.

As further shown in FIG. 1, device 100 comprises an amorphous carbon (a-C) layer 110 formed over patterned hard mask 104, an antireflective coating (ARC) 112 over a-C layer 110, and a photoresist 114 formed over ARC 112.

Next, as shown with semiconductor device 200 in FIG. 2, ARC 212 is etched selective to a-C layer 210. A portion of ARC 212 below photoresist 214 is protected however, and remains following the etch process.

A masking structure 314 is then formed, as shown with semiconductor device 300 in FIG. 3, by removing those portions of a-C layer 310 left uncovered by ARC 312. As depicted, masking structure 314 is formed over a first section 304-A of the patterned hard mask, while a second section 304-B of the patterned hard mask remains exposed following removal of a-C layer 310.

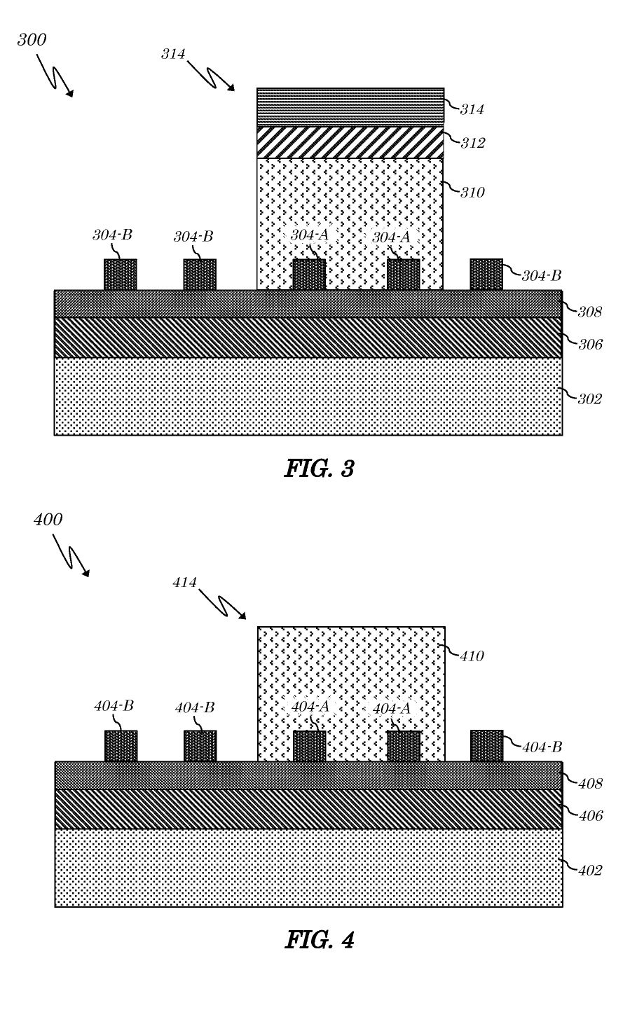

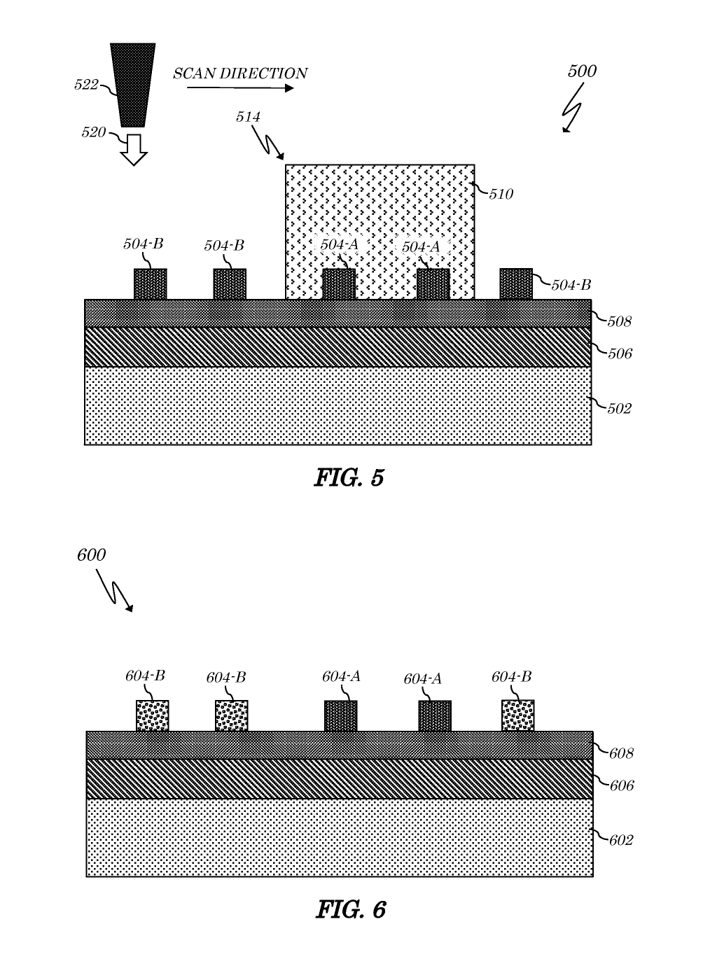

ARC 312 is then removed, as shown by semiconductor device 400 in FIG. 4, and device 500 is annealed, as shown in FIG. 5. In this embodiment, a high temperature crystallization anneal process 520 is performed to crystalize second sections 504-B of the hard mask. Masking structure 514 prevents first section 504-A from being crystallized during anneal 520. It will be appreciated that device 500 can be annealed using any number of high temperature annealing processes to enhancing the quality of the high-k material of second sections 504-B. The annealing process can be performed in any type of suitable reactor chamber (not shown). The suitable reactor chambers can execute a rapid thermal process (RTP) such as a spike rapid thermal process or a soak rapid thermal process, a laser spike annealing process, a flash annealing process, a dynamic surface annealing process or any combination of annealing processes.

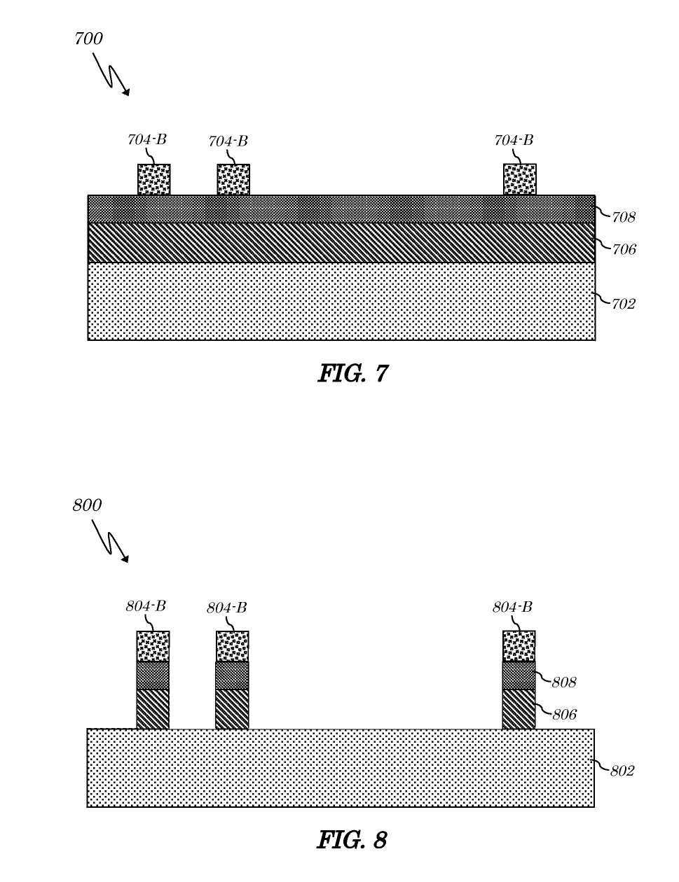

Once crystallization is complete, masking structure 514 is removed from atop first section 604-A of the patterned hard mask, as shown by semiconductor device 600 in FIG. 6, resulting in a hard mask comprising a set of crystallized hard mask elements (i.e., second section 604-B) adjacent a set of non-crystallized hard mask elements (i.e., first section 604-A). The non-crystallized hard mask elements of first section 604-A are then removed to eliminate the fin hard mask from a fin cut mask area of device 700, as shown with semiconductor device 700 in FIG. 7. In one embodiment, the non-crystallized hard mask elements of first section 604-A are removed using a wet clean process in which a wet etch is performed using a hydrogen fluoride (HF) solution.

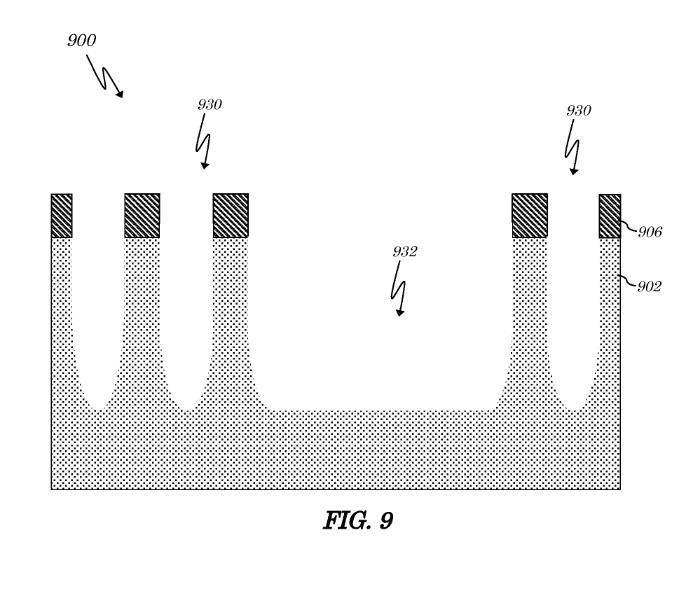

Next, undoped oxide 808 and second hard mask 806 are etched, as shown with semiconductor device 800 in FIG. 8, wherein portions of oxide 808 and second hard mask 806 remain beneath the crystallized hard mask elements of second section 804-B. Finally, a set of fins 930 is formed in device 900, as shown in FIG. 9. Second hard mask 906 remains atop each of set of fins 930 following fin formation. As shown, no fins are present in fin cut mask area 932. By processing device 900 this way, both incomplete removal of second hard mask 906 and/or unintended partial removal of second hard mask 906 are eliminated.

Fins 930 may be fabricated using reactive ion etch (RIE) and/or other suitable processes. In one embodiment, fins 930 have small dimensions (e.g., <20 nm) and pitches (<90 nm) and, as such, are formed by a double-patterning lithography (DPL) process. DPL is a method of constructing a pattern on a substrate by dividing the pattern into two interleaved patterns. DPL allows enhanced feature (e.g., fin) density. Various DPL methodologies may used including, double exposure (e.g., using two mask sets), forming spacers adjacent features and removing the features to provide a pattern of spacers, resist freezing, and/or other suitable processes.

Although not shown, it will be appreciated that a set of gate stack structures may be subsequently formed atop device 900. In one embodiment, the gate stack structure includes a gate dielectric layer and a metal gate electrode stack. Numerous other layers may also be present, for example, capping layers, interface layers, spacer elements, and/or other suitable features. The gate dielectric layer may include dielectric material such as, silicon oxide, silicon nitride, silicon oxynitride, dielectric with a high dielectric constant (high k), and/or combinations thereof. The gate dielectric layer may be formed using processes such as, photolithography patterning, oxidation, deposition, etching, and/or other suitable processes. The gate electrode may include polysilicon, silicon-germanium, a metal including metal compounds such as, Mo, Cu, W, Ti, Ta, TiN, TaN, NiSi, CoSi, and/or other suitable conductive materials known in the art. The gate electrode may be formed using processes such as, physical vapor deposition (PVD), CVD, plasma-enhanced chemical vapor deposition (PECVD), atmospheric pressure chemical vapor deposition (APCVD), low-pressure CVD (LPCVD), high density plasma CVD (HD CVD), atomic layer CVD (ALCVD), and/or other suitable processes which may be followed, for example, by photolithography and/or etching processes. In one embodiment, the gate structure comprises a replacement (i.e., dummy) metal gate (RMG), which may be formed using any now known or later developed techniques, e.g., material deposition, mask material deposition, patterning, etching, etc., to form the RMG structure.

Furthermore, in various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also be comprised of hardware, software, or a combination thereof. Thus, for example, a tool can be a collection of one or more software modules, hardware modules, software/hardware modules, or any combination or permutation thereof, for performing the processing steps shown in FIGS. 1-9. In an exemplary embodiment, the design tool is configured to: pattern a hard mask over a substrate; and form a set of crystallized hard mask elements adjacent a set of non-crystallized hard mask elements of the hard mask.

As another example, a tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines, or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided an approach for forming a fin field-effect-transistor (FinFET) device using a partially crystallized fin hard mask. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A semiconductor device comprising:
a substrate; and
a hard mask patterned over the substrate, the hard mask comprising a set of crystallized hard mask elements adjacent a set of non-crystallized hard mask elements.

2. The semiconductor device according to claim 1, the hard mask comprising a high-k material.

3. The semiconductor device according to claim 1, further comprising a second hard mask formed over the substrate.

4. The semiconductor device according to claim 3, the second hard mask comprising nitride.

5. The semiconductor device according to claim 3, further comprising an undoped oxide over the second hard mask.

6. A method for forming a fin field-effect-transistor (FinFET) device, the method comprising:
patterning a hard mask over a substrate; and
forming a set of crystallized hard mask elements adjacent a set of non-crystallized hard mask elements of the hard mask.

7. The method according to claim 6, further comprising forming a masking structure over a first section of the patterned hard mask.

8. The method according to claim 7, the forming the set of crystallized hard mask elements comprising annealing the FinFET device, wherein the masking structure prevents the set of non-crystallized hard mask elements from being crystallized during the annealing.

9. The method according to claim 7, the forming the masking structure comprising:
forming an amorphous carbon (a-C) layer over the patterned hard mask;
forming an antireflective coating over the a-C layer;
forming a photoresist over the first section of the patterned hard mask; and
removing the a-C layer and the antireflective coating from over a second section of the patterned hard mask.

10. The method according to claim 9, further comprising:
removing the antireflective coating from atop the masking structure prior to the annealing;
removing the a-C from the first section of the patterned hard mask following the annealing;
removing the non-crystallized hard mask elements; and
etching the substrate to form a set of fins.

11. The method according to claim 10, wherein the second hard mask remains atop each of the set of fins.

12. The method according to claim 6, further comprising:
forming a second hard mask over the substrate; and
forming an undoped oxide over the second hard mask.

13. The method according to claim 12, the hard mask comprising a high-k material, and the second hard mask comprising nitride.

14. A method for forming a fin field-effect-transistor (FinFET) device using a partially crystallized fin hard mask, the method comprising:
patterning a hard mask over a substrate; and
annealing the hard mask to form a set of crystallized hard mask elements adjacent a set of non-crystallized hard mask elements.

15. The method according to claim 14, further comprising forming a masking structure over a first section of the patterned hard mask, wherein the masking structure prevents the set of non-crystallized hard mask elements from being crystallized during the annealing.

16. The method according to claim 15, the forming the masking structure comprising:
forming an amorphous carbon (a-C) layer over the patterned hard mask;
forming an antireflective coating over the a-C layer;
forming a photoresist over the first section of the patterned hard mask; and
removing the a-C layer and the antireflective coating from over a second section of the patterned hard mask.

17. The method according to claim 16, further comprising:
removing the antireflective coating from atop the masking structure prior to the annealing;
removing the a-C from the first section of the patterned hard mask following the annealing;
removing the non-crystallized hard mask elements; and
etching the substrate to form a set of fins.

18. The method according to claim 17, wherein the second hard mask remains atop each of the set of fins.

19. The method according to claim 14, further comprising:
forming a second hard mask over the substrate; and
forming an undoped oxide over the second hard mask.

20. The method according to claim 19, the hard mask comprising a high-k material, and the second hard mask comprising nitride.
